(19) United States
(12) Patent Application Publication
(10) Pub. No.: US 2016/0135308 A1
(43) Pub. Date: May 12, 2016

(54) PROTECTIVE CASE FOR ELECTRONIC DEVICE

(71) Applicant: TAER INNOVATION CO., LTD., NEW TAIPEI CITY (TW)

(72) Inventor: CHIH-SHENG WANG, NEW TAIPEI CITY (TW)

(21) Appl. No.: 14/695,180

(22) Filed: Apr. 24, 2015

(30) Foreign Application Priority Data
Nov. 7, 2014 (TW) 103219783

(51) Int. Cl. H05K 5/02; A45C 11/00; H05K 5/00

(52) U.S. Cl. CPC H05K 5/0217; H05K 5/0086; H05K 5/0013; A45C 11/00; A45C 2011/002; A45C 2011/003

(57) ABSTRACT

The present disclosure provides a protective case for an electronic device which includes a case unit and a key unit. The case unit includes a first side portion, a second side portion and a groove portion. A capacity space is formed between the first side portion and the second side portion. The groove portion includes a first groove body and a second groove body. The first groove body is disposed on the first side portion, the second groove body is disposed on the second side portion. The key unit includes a first key element. The first key element includes an abutment portion. The abutment portion includes a first abutting end and a second abutting end. The first abutting end and the second abutting end are correspondingly disposed. The first abutting end abuts against the first groove body, and the second abutting end abuts against the second groove body.

### BACKGROUND

1. Field of the Invention

The instant disclosure relates to a structure of a protective case for an electronic device, and in particular, relates to a protective case for an electronic device which can be used to contain a mobile device.

2. Description of Related Art

As modern technology continues to progress, mobile devices, such as smart phones, the tablet PC or notebooks, contain more and more functions. Users can not only make a phone call to communicate with others, but also surf the Internet, watch video, listen to music or work through the mobile device.

Therefore, in order to prevent mobile device from abrasion or surficial blemishes caused by friction or physical impact, consumers will put their mobile devices, such as cell phones and tablet PCs, into a protective case to protect the surface of the electronic device, thereby reducing the possibility of damage to the electronic device. At present, most electronic devices have multiple keys, like a power key, volume key and mute key.

Thereby, for matching to various keys of the electronic device, a protective case will be designed to have openings corresponding to those keys to expose the keys of the electronic device. However, the protective case which exposes various keys still causes those keys of the electronic device to have abrasion or surficial blemishes made by friction or physical impact.

### SUMMARY OF THE INVENTION

In view of the above, the instant disclosure provides a protective case for an electronic device which can protect the keys of the mobile device through key units disposed on the protective case for the electronic device. Meanwhile, the design of the key units allows users to change them easily, therefore, the case unit and key unit can have different replacements.

In order to reach the purpose mentioned above, one of embodiments of the instant disclosure provides a protective case for an electronic device which includes a case unit and a key unit. The case unit includes a first side portion, a second side portion and a groove portion, and a first capacity space is formed between the first side portion and the second side portion, and the groove portion includes a first groove body and a second groove body, and the first groove body is disposed on the first side portion, and the second groove body is disposed on the second side portion. The key unit includes a first key element, and the first key element includes an abutment portion, and the abutment portion includes a first abutting end and a second abutting end, and the first abutting end and the second abutting end are correspondingly disposed. And the first abutting end abuts against the first groove body, and the second abutting end abuts against the second groove body.

Another embodiment of the instant disclosure provides a protective case for an electronic device which includes a case unit and a key unit. The case unit includes a second capacity space and a capacity tank. The second capacity space and the capacity tank are correspondingly disposed. The key unit includes a second key element, and the second key element includes a second key portion and a clamping portion. The second key portion is disposed in the second capacity space, and the clamping portion is disposed in the capacity tank.

The benefit of the instant disclosure is to provide a protective case for an electronic device, through the designed structure between the case unit and the first key element and between the case unit and the second key element, to make the first key element and the second key element stably disposed in the first capacity space and the second capacity space on the case unit, meanwhile, allowing users to easily replace the first key element and the second key element with different colors on the case unit.

In order to further understand the techniques, means and effects of the instant disclosure, the following detailed descriptions and appended drawings are hereby referred to, such that, and through which, the purposes, features and aspects of the instant disclosure can be thoroughly and concretely appreciated; however, the appended drawings are merely provided for reference and illustration, without any intention to be used for limiting the instant disclosure.

### BRIEF DESCRIPTION OF THE DRAWINGS

FIG. 1 illustrates a using state diagram of a protective case for an electronic device according to an embodiment of the instant disclosure.

FIG. 2A illustrates a stereogram of the protective case for an electronic device according to a first embodiment of the instant disclosure.

FIG. 2B illustrates an enlarged schematic view of part A in FIG. 2A.

FIG. 2C illustrates an enlarged exploded perspective view of part A in FIG. 2A.

FIG. 2D illustrates one stereogram of a first key element according to a first embodiment of the instant disclosure.

FIG. 2E illustrates another stereogram of a first key element according to a first embodiment of the instant disclosure.

FIG. 2F illustrates a cross-sectional view of the first key element according to a first embodiment of the instant disclosure.

FIG. 2G illustrates an enlarged exploded partial cross-sectional view of the protective case for an electronic device according to a first embodiment of the instant disclosure.

FIG. 2H illustrates an enlarged partial cross-sectional view of the protective case for an electronic device according to a first embodiment of the instant disclosure.

FIG. 3A illustrates a stereogram of the protective case for an electronic device according to a first embodiment of the instant disclosure.

FIG. 3B illustrates an enlarged schematic view of part B in FIG. 3A.

FIG. 3C illustrates an enlarged exploded perspective view of part B in FIG. 3A.

FIG. 3D illustrates one stereogram of a second key element according to a second embodiment of the instant disclosure.

FIG. 3E illustrates another stereogram of a second key element according to a second embodiment of the instant disclosure.

### DETAILED DESCRIPTION OF THE PREFERRED EMBODIMENTS

The accompanying drawings show some exemplary embodiments, and a more detailed description of various embodiments with reference to the accompanying drawings in accordance with the present disclosure is set forth below. The concept of the invention may be embodied in many different forms and must not be construed as limited to the embodiment set forth herein. To be more precise, the exemplary embodiments set forth herein are provided so a person of ordinary skill in the art can thoroughly and completely understand the contents disclosed herein and fully provide the spirit of the invention. In each of the drawings, the relative size, proportions, and depiction of the layers and regions in the drawings may be exaggerated for clarity and precision, in which like numerals indicate like elements.

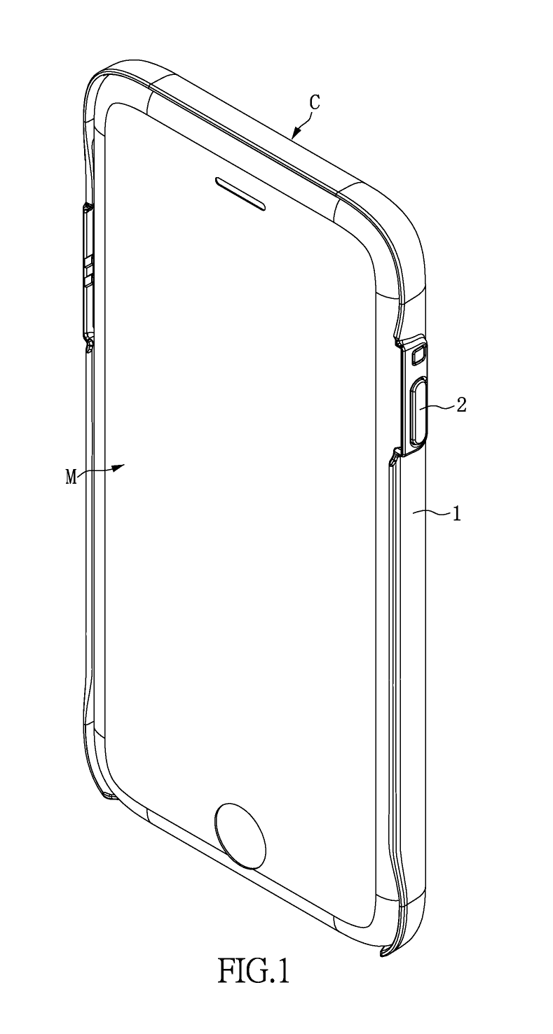

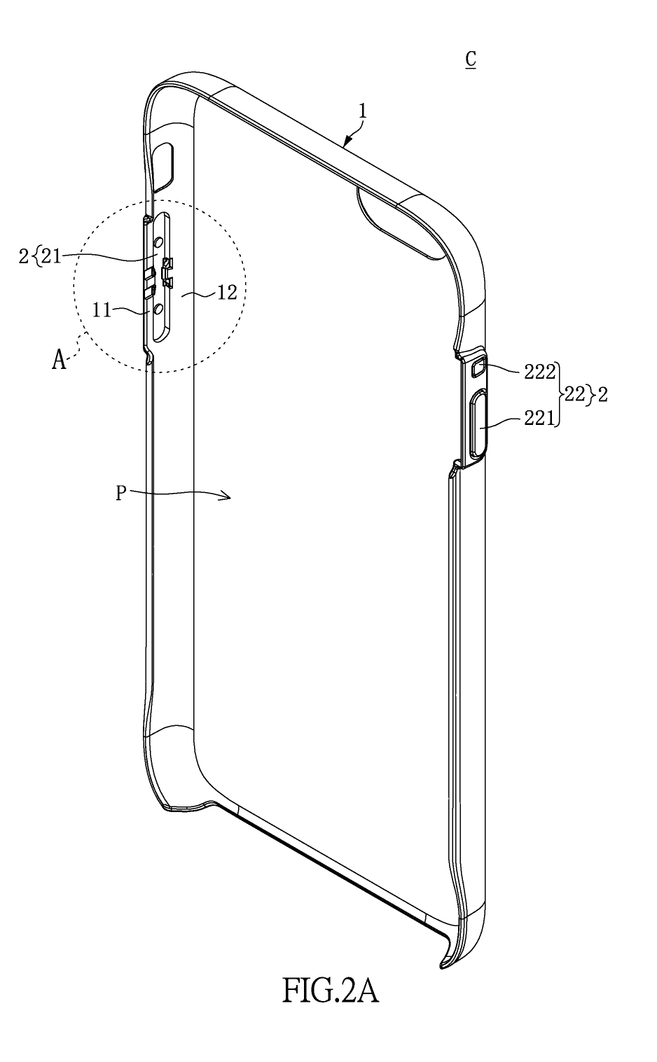

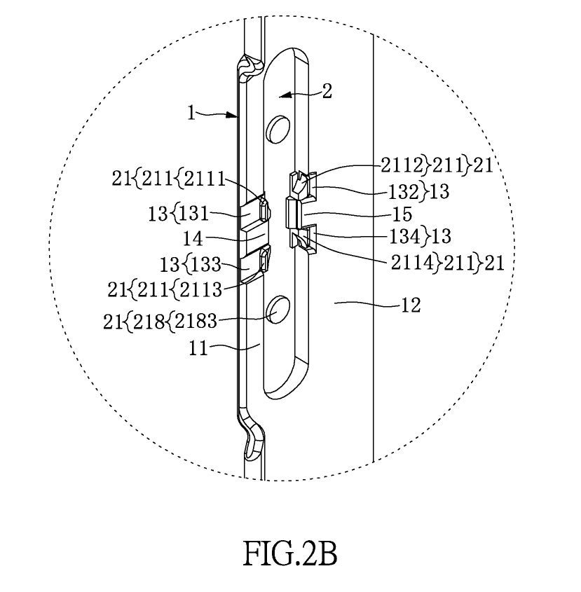

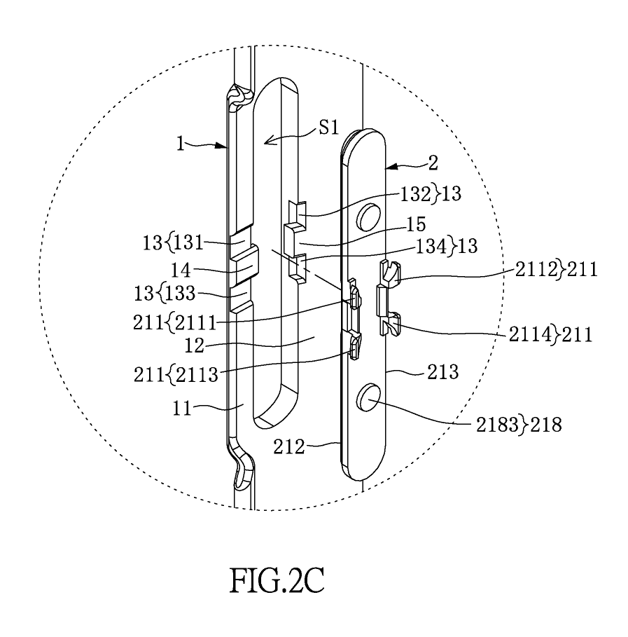

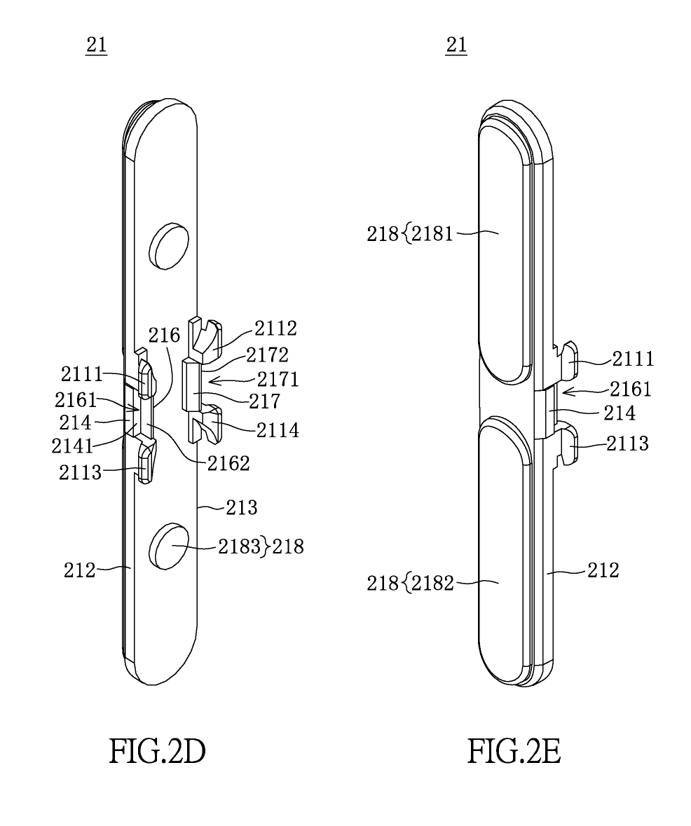

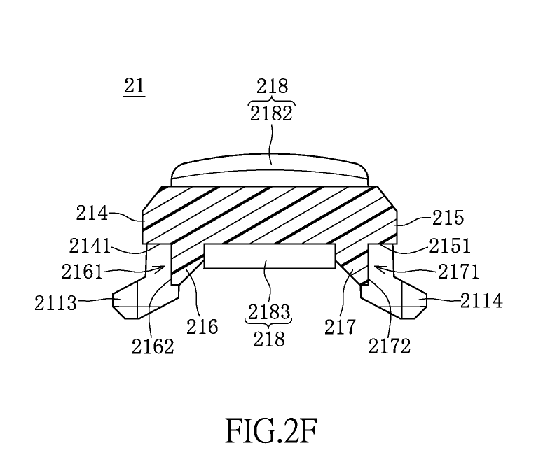

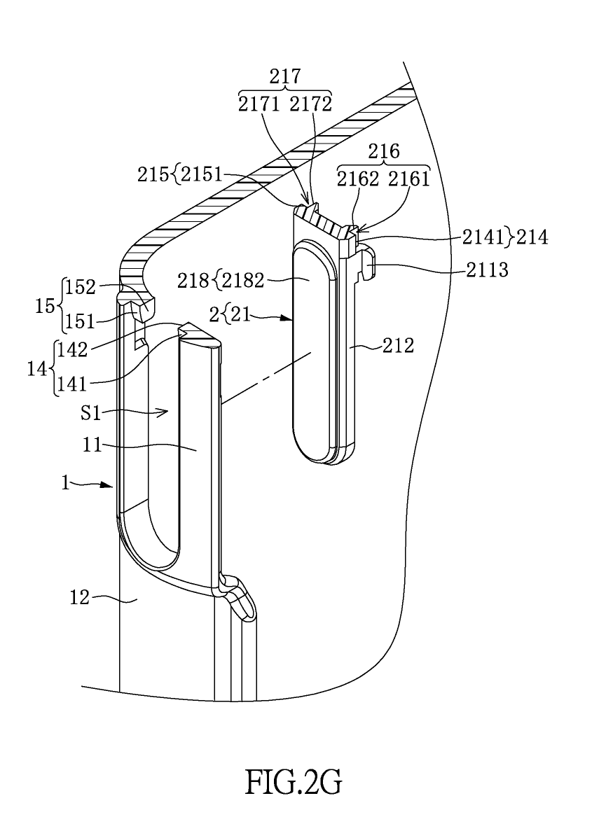

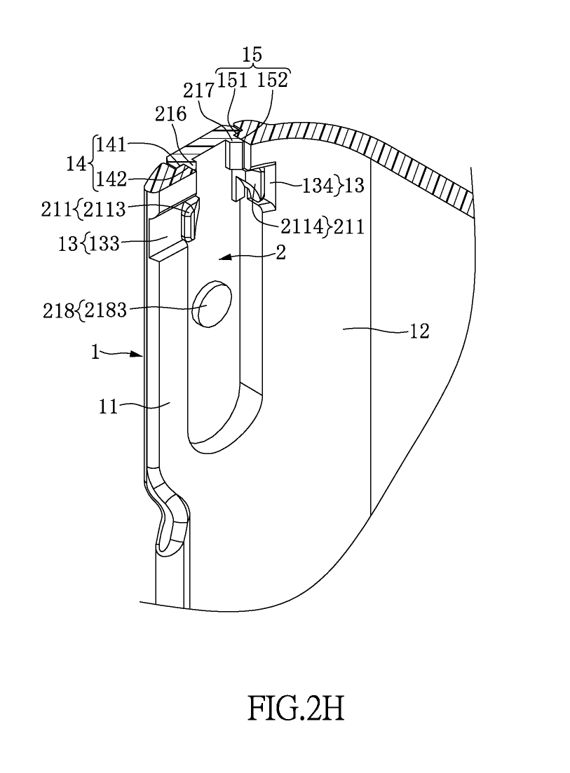

First, please refer to FIG. 1 and FIG. 2A. FIG. 1 illustrates a using state diagram of a protective case for an electronic device according to an embodiment of the instant disclosure. FIG. 2A illustrates a stereogram of the protective case for an electronic device according to first embodiment of the instant disclosure. A protective case C for an electronic device includes a case unit 1 and a key unit 2. The protective case C has a receiving portion P to contain a mobile device M. The mobile device M, may be a smartphone or tablet PC, and can be contained within the receiving portion P. Namely, the protective case C is used for containing and protecting the mobile device M. In practice, the protective case C may be elastic to contain the mobile device M. For example, the material of the case unit 1 can be Polycarbonate (PC), and the material of the key unit 2 can be electroplating ABS plastic (Acrylonitrile butadiene styrene, ABS).

Please refer to FIG. 2B to 2E. FIG. 2B illustrates an enlarged schematic view of part A in FIG. 2A. FIG. 2C illustrates an enlarged exploded perspective view of part A in FIG. 2A. FIG. 2D illustrates one stereogram of a first key element according to a first embodiment of the instant disclosure. FIG. 2E illustrates another stereogram of a first key element according to a first embodiment of the instant disclosure. One side of the case unit 1 can includes a first side portion 11, a second side portion 12 and a groove portion 13. A first capacity space S1 is formed between the first side portion 11 and the second side portion 12 to contain the key unit 2. The groove portion 13 can include a first groove body 131 and a second groove body 132. The first groove body 131 can be disposed on the first side portion 11, and the second groove body 132 can be disposed on the second side portion 12.

As above, the key unit 2 can include a first key element 21, and the first key element 21 can include an abutment portion 211, and the abutment portion 211 can include an abutting end 2111 and a second abutting end 2112. The first abutting end 2111 and the second abutting end 2112 are correspondingly disposed. For example, the first abutting end 2111 and second abutting end 2112 are respectively disposed on two opposite sides of the first key element 21. The first abutting end 2111 can abut against the first groove body 131, and the second abutting end 2112 can abut against the second groove body 132. Thereby, when the mobile device M is placed on the receiving portion P of the case unit 1, the keys (not shown) of the mobile device M, like volume key, can abut against the first key element 21 and the abutting portion 211 on the first element 21 can abut against the groove portion 13 on the case unit 1. In addition, the key element 21 further includes a first key portion 218, and the first key portion 218 includes a first key end 2181 and a second key end 2182, and the abutting portion 211 is disposed between the first key end 2181 and the second key end 2182. Therefore, when a user presses the first key end 2181 or a protruding block 218 of the second key end 2182, the key of the mobile device M can be indirectly pressed.

Preferably, in the first embodiment of the instant disclosure, the groove portion 13 on the case unit 1 can further include a third groove body 133 and a fourth groove body 134. The third groove body 133 and the fourth groove body 134 are correspondingly disposed. The abutment portion 211 on the first key element 21 can further include a third abutting end 2113 and a fourth abutting end 2114, and the third abutting end 2113 and the fourth abutting end 2114 are correspondingly disposed. Specifically, the third groove body 133 can be disposed on the first side portion 11 of the case unit 1, and the fourth groove body 134 is disposed on the second side portion 12 of the case unit 1. The third abutting end 2113 and the fourth abutting end 2114 can be respectively disposed on two opposite sides of the key element 21. To be specific, the key element 21 can further include a first side surface 212 and a second side surface 213, and the first side surface 212 and the second side surface 213 are correspondingly disposed. Specifically, the first side surface 212 and the second side surface 213 are respectively disposed on the opposite sides of the key element 21. The first abutting end 2111 and the third abutting end 2113 can be disposed on the first side surface 212, and the second abutting end 2112 and the fourth abutting end 2114 can be disposed on the second side surface 213. Thereby, the third abutting end 2113 can abut against the third groove body 133, and the fourth abutting end 2114 can abut against the fourth groove body 134 so as to enhance the connectivity between the first key element 21 and the case unit 1.

In view of the above, preferably, the first abutting end 2111 and the third abutting end 2113 are disposed next to each other with a predetermined distance, and the second abutting end 2112 and the fourth abutting end 2114 are disposed next to each other with a predetermined distance. The first groove body 131 and the third groove body 133 are disposed next to each other with a predetermined distance, and the second groove body 132 and the fourth groove body 134 are disposed next to each other with a predetermined distance. Therefore, the case unit 1 can further include a first protruded portion 14 and a second protruded portion 15. The first protruded portion 14 can be disposed between the first groove body 131 and the third groove body 133 and can stretch into the first capacity space S1. The second protruded portion 15 can stretch into the first capacity space S1. In addition, preferably, the second protruded portion 15 can have a second protruded surface 151 which can cooperate with the first key element 21.

Please refer to FIG. 2F to 2H and FIG. 2D and 2E. FIG. 2F illustrates a cross-sectional view of the first key element according to a first embodiment of the instant disclosure. FIG. 2G illustrates an enlarged exploded partial cross-sectional view of the protective case for an electronic device according to a first embodiment of the instant disclosure. FIG. 2H illustrates an enlarged partial cross-sectional view of the protective case for an electronic device according to a first embodiment of the instant disclosure. In the figures, the first key element 21 can further include a first top contact portion 214 and a second top contact portion 215. The first top contact portion 214 is protrudingly disposed on the first side surface 212, and the second top contact portion 215 is protrudingly disposed on the second side surface 213. The first top contact portion 214 has a first top contact surface 2141, and the second top contact portion 215 has a second top contact surface 2151. Thereby, when the first key element 21 is disposed in the first capacity space S1 of the case unit 1, the first top contact surface 2141 will abut against the first protruded surface 141 of the case unit 1 and the second top contact surface 2151 will abut against the second protruded surface 151 of the case unit 1.

In view of the above, the key element 21 can further include a first connecting portion 216 and a second connecting portion 217. The first connecting portion is disposed between the first abutting end 2111 and the third abutting end 2113. The upper surface 2162 of the first connecting portion 216 is apart from the first side surface 212 with a predetermined distance to define a first slot 2161. The second connecting portion is disposed between the second abutting end 2112 and the fourth abutting end 2114, and the upper surface 2172 of the second connecting portion 217 is apart from the second side surface 213 with a predetermined distance to define a second slot 2171.

In view of the above, specifically, in FIG. 2F, the first top contact portion 214 and the second top contact portion 215 of first key element 21 are respectively slightly protruded from the first side surface 212 and the second side surface 213. The part of first top contact portion 214 which is slightly protruded from the first side surface 212 has a first top contact surface 2141, and the part of the second top contact portion 215 which is slightly protruded from the second side surface 213 has a second top contact surface 2151. In FIG. 2G and 2H, the first protruded portion 14 of the case unit 1 can be disposed on the first side portion 11, and the second protruded portion 15 can be disposed on the second side portion 12. Thereby, the first protruded surface 141 of the first protruded portion 14 can be protrudingly disposed on the first side portion 11 and expand into the first capacity space S1. The second protruded surface 151 of the second protruded portion 15 can be protrudingly disposed on the second side portion 12 and expand into the first capacity space S1.

In view of the above, when a user wants to dispose the first key element 21 in the first capacity space S1, the user can make the first abutment portion 214 and the second abutment portion 215 of the first key element 21 to enlarge the distance between the first side portion 11 and second side portion 12 of the case unit 1 through the inherent flexibility of the case unit 1 so as to contain the first key element 21. Then, when the first key element 21 is disposed on the case unit 1, the first abutting surface 2141 will abut against the first protruded surface 141 of the case unit 1 and the second abutting surface 2151 will abut against the second protruded surface 151 of the case unit 1. Preferably, the first protruded portion 14 can be contained within the first slot 2161 and the top surface 142 of the first protruded portion 14 can be apart from the upper surface 2162 of the first connecting portion 216 with a predetermined distance. The second protruded portion 15 can be contained within the second slot 2171 and the top surface 152 of the second protruded portion 15 can be apart from the upper surface 2172 of the second connecting portion 217 with a predetermined distance. Thereby, when the upper surface 142 of the first protruded portion 14 is apart from the upper surface 2162 of the first connecting portion 216 with a predetermined distance and the upper surface 152 of the second protruded portion 15 is apart from the upper surface 2172 of the second connecting portion 217 with a predetermined distance, the first key element 21 can pass through the abutment between the first abutting surface 2141, the second abutting surface 2151, the first protruded surface 141 and the second protruded surface 151. Meanwhile, the first key element 21 can also pass through the abutment between the groove portion 13 and the abutment portion 211, and makes the first key end 2181 and the second key end 2182 of the first key element 21 swing in the first capacity space S1 by the inherent flexibility of the first key element 21. In addition, for example, the upper surface 142 of the first protruded portion 14 can also abut against the upper surface 2162 of the first connecting portion 216, the top surface 152 of the second protruded portion 15 can also abut against the upper surface 2172 of the second connecting portion 217, but is not limited to the example provided herein.

In view of the above, by the abutment between the first protruded portion 14, the second protruded portion 15, the first top contact portion 214 and the second top contact portion 215 of the first key element 21, when a user presses the first key end 2181 and the second key end 2182, the user can regard all of the first protruded portion 14, the second protruded portion 15, the first top contact portion 214 and the second top contact portion 215 as a pivot axis. Meanwhile, by making the first groove body 131, the second groove body 132, the third groove body 133 and the fourth groove body 134 on the case unit 1 respectively abut against the first abutting end 2111, the second abutting end 2112, the third abutting end 2113 and the fourth abutting end 2114 of the first key element 21, the first key element 21 will not easily get loose from the case unit 1. When a user want to replace the first key element 21 with different colors, the user can also take the first key element 21 out by using the inherent flexibility of the case unit 1.

In the first embodiment, the first key element 21 is disposed in the first capacity space S1 through the abutment between the first protruded portion 14 and the second protruded portion 15 of the case unit 1 and the first abutment portion 214 and the second abutment portion 215 of the first key element 21. Meanwhile, the first key element 21 will not easily get loose from the case unit 1 by the abutment between the groove portion 13 of the case unit 1 and the abutment portion 211 of the first key element 21.

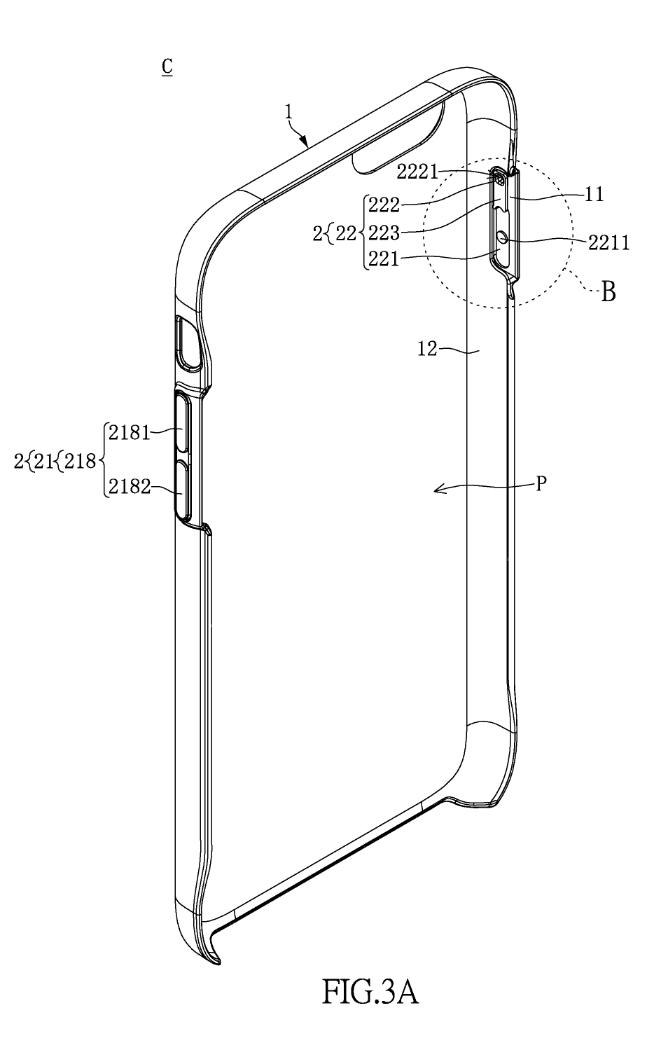

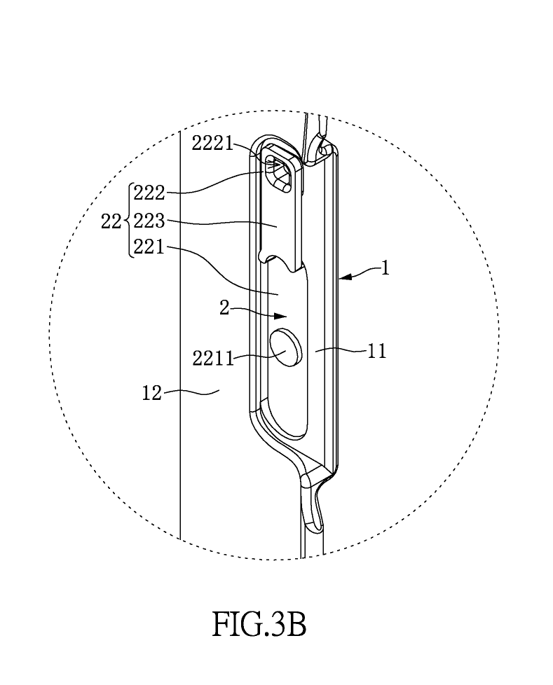

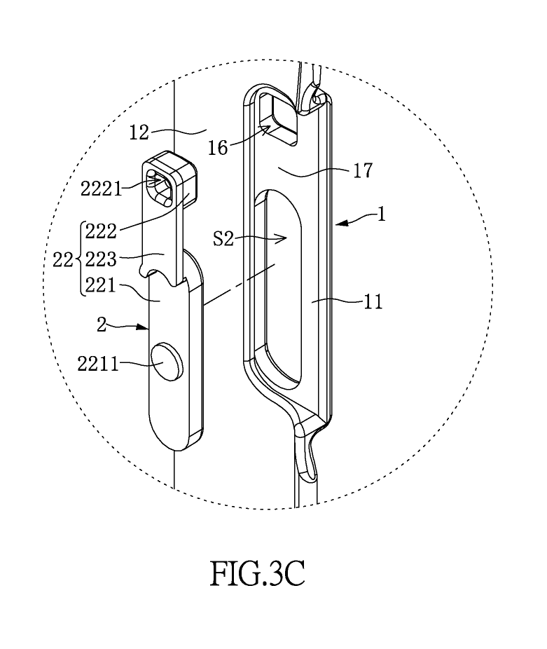

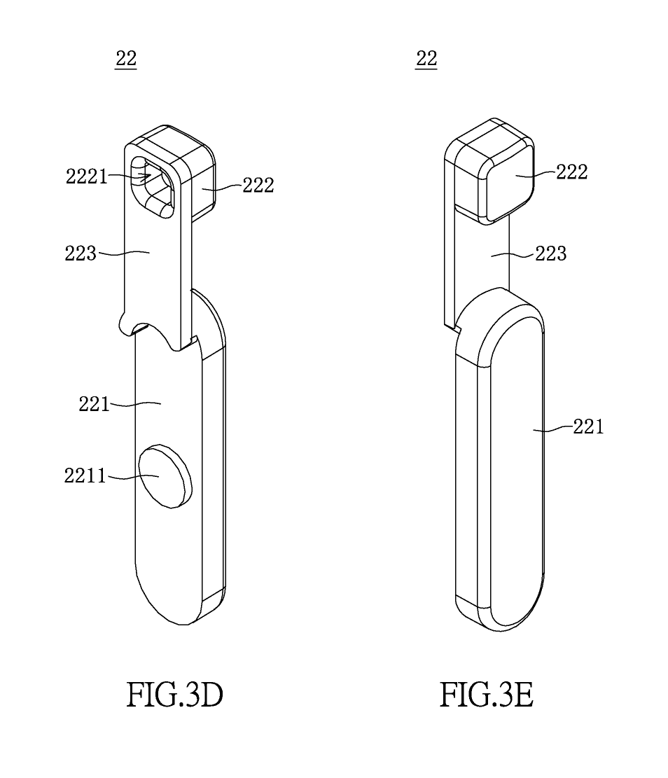

Please refer to FIG. 3A to 3E. FIG. 3A illustrates a stereogram of the protective case for an electronic device according to a first embodiment of the instant disclosure. FIG. 3B illustrates an enlarged schematic view of part B in FIG. 3A. FIG. 3C illustrates an enlarged exploded perspective view of part B in FIG. 3A. FIG. 3D illustrates one stereogram of a second key element according to a second embodiment of the instant disclosure. FIG. 3E illustrates another stereogram of a second key element according to a second embodiment of the instant disclosure. Comparing FIG. 3A to FIG. 2A, the differences between the second embodiment and the first embodiment are that the second key element 22 provided in the second embodiment can directly combine with the case unit 1 through the clamping portion 222 disposed on the second key element 22.

The second embodiment of the instant disclosure provides a protective case for an electronic device C which includes a case unit 1 and a key unit 2. The other side of the case unit 1 can include a second capacity space S2 and a capacity tank 16. The second capacity space S2 and the capacity tank 16, and the second capacity space S2 and the capacity tank 16 are correspondingly disposed. Specifically, the case unit 1 can include a first side portion 11 and a second side portion 12. The second capacity space S2 can be formed between the first side portion 11 and a second side portion 12. The key unit 2 can include a second key element 22, and the second key element 22 can include a second key portion 221 and a clamping portion 222. The second key portion 221 can be disposed in the second capacity space S2, and the clamping portion 222 can be disposed in the capacity tank 16.

In view of the above, the second key element 22 further includes a stick body 223, and the stick body 223 is disposed between the second key portion 221 and the clamping portion 222 to connect the second key portion 221 and the clamping portion 222. In addition, for example, the clamping portion 222 further includes a flute 2221, and the second key portion 221 can further include a protruding block 2211. Thereby, when a user presses the second key portion 221 exposed to the case unit 1, the protruding block 2211 disposed on the second key portion 221 will indirectly abut against the press the key on the mobile device M (not shown). Since the clamping portion 222 is disposed in the capacity tank 16 and the second key portion 221 is disposed in the second capacity space S2, the stick body 223 and the second key portion 221 can be bend relative to the clamping portion 222 to abut against the key of the mobile device M. In addition, the case unit 1 can has a bridge portion 17, and the bridge portion 17 can be disposed between the second capacity space S2 and the capacity tank 16 to connect the capacity space S2 with the capacity tank 16. When the second key element 22 is disposed on the case unit 1, the stick body 223 will abut against the bridge portion 17 of the case unit 1. It's worth to mention that the appearance from the second key portion 221 to the stick body 223 is stepped, and the stepped appearance can contain the keys of the mobile device M.

In the second embodiment, the first key element 21 can combine with the case unit 1 through the close engagement of the capacity tank 16 of the case unit 1 and the clamping portion 222 of the first key element 21. In addition, after user press the first element 21, the stick body 223 of the second key element 22 can also provide an elastic force to make the second key portion 221 bounce back to the second capacity space S2.

First, please refer to FIG. 2A and 3A. The third embodiment of the instant disclosure provides a protective case C for an electronic device which includes a case unit 1 and a key unit 2. And the protective case for an electronic device C provided in the third embodiment can also have a first key element 21 and a second key element 22. In the third embodiment, the one side of the case unit 1 includes a first side portion 11, a second side portion 12 and a groove portion 13. A first capacity space S1 is formed between the first side portion 11 and the second side portion 12. The groove portion 13 includes a first groove body 131 and a second groove body 132. The first groove body 131 is disposed on the first side portion 11, and the second groove body 132 is disposed on the second side portion 12. Another side of the case unit 1 includes a second capacity space S2 and a capacity tank 16, and the second capacity space S2 and the capacity tank 16 are correspondingly disposed. The key unit 2 can include a first key element 21 and a second key element 22. The first key element 21 includes an abutment portion 211, and the abutment portion 211 includes a first abutting end 2111 and a second abutting end 2112. The first abutting end 2111 and the second abutting end 2112 are correspondingly disposed. The first abutting end 2111 abuts against the first groove body 131, and the second abutting end 2112 abuts against the second groove body 132. The second key element 22 includes a second key portion 221 and a clamping portion 222. And the second key portion 221 is disposed in the second capacity space S2, and the clamping portion 222 is disposed in the capacity tank 16. In addition, the details of the case unit 1, the first key element 21 and the second key element 22 provided in the third embodiment refer to the foregoing description, and the common features are not described again.

In summary, the present disclosure provides a protective case C for an electronic device which can allow a user to easily dismantle the key unit 2 and replace it with other different colored key units 2 through the combination between the case unit 1 and the key unit 2.

The above-mentioned descriptions represent merely the exemplary embodiment of the instant disclosure, without any intention to limit the scope of the instant disclosure thereto. Various equivalent changes, alterations or modifications based on the claims of instant disclosure are all consequently viewed as being embraced by the scope of the present disclosure.

What is claimed is:

1. A protective case for an electronic device, comprising:
a case unit including a first side portion, a second side portion and a groove portion, and a first capacity space formed between the first side portion and the second side portion, and the groove portion including a first groove body and a second groove body, wherein the first groove body is disposed on the first side portion and the second groove body is disposed on the second side portion; and
a key unit including a first key element, and the first key element including an abutment portion, and the abutment portion including a first abutting end and a second abutting end, and the first abutting end and the second abutting end are disposed correspondingly;
wherein the first abutting end abuts against the first groove body and the second abutting end abuts against the second groove body.

2. The protective case for an electronic device according to claim 1, wherein the groove portion further includes a third groove body and a fourth groove body, and the third groove body and the fourth groove body are disposed correspondingly, and the abutment portion further includes a third abutting end and a fourth abutting end, and the third abutting end and the fourth abutting end are disposed correspondingly, and the third groove body is disposed on the first side portion, the fourth groove body is disposed on the second side portion, and the third abutting end abuts against the third groove body, the fourth abutting end abuts against the fourth groove body.

3. The protective case for an electronic device according to claim 2, wherein the case unit further includes a first protruded portion and a second protruded portion, and the first protruded portion is disposed between the first groove body and the third groove body and stretches into the first capacity space, and the second protruded portion is disposed between the second groove body and the fourth groove body and stretches into the first capacity space, wherein the first protruded portion has a first protruded surface and the second protruded portion has a second protruded surface.

4. The protective case for an electronic device according to claim 3, wherein the first key element further includes a first side surface, a second side surface, a first top contact portion, a second top contact portion, and the first side surface and second side surface are disposed correspondingly, and the first top contact portion is protrudingly disposed on the first side surface and the second top contact portion is protrudingly disposed on the second side surface, and the first top contact portion has a first top contact surface and the second top contact portion has a second top contact surface, and the first top contact surface abuts against the first protruded surface and the second contact surface abuts against the second protruded surface.

5. The protective case for an electronic device according to claim 4, wherein the first key element further includes a first connecting portion and a second connecting portion, and the first connecting portion is disposed between the first abutting end and the third abutting end to define a first slot, and the second connecting portion is disposed between the second abutting end and the fourth abutting end to define a second slot.

6. The protective case for an electronic device according to claim 5, wherein the first protruded portion is contained in the first slot, and the second protruded portion is contained in the second slot.

7. The protective case for an electronic device according to claim 1, wherein the key element further includes a first key portion, and the first key portion includes a first key end and a second key end, and the abutting portion is disposed between the first key end and the second key end.

8. A protective case for an electronic device, comprising:
a case unit including a second capacity space and a capacity tank, wherein the second capacity space and the capacity tank are correspondingly arranged;
a key unit including a second key element, and the second key element including a second key portion and a clamping portion;
wherein the second key portion is disposed in the second capacity space, and the clamping portion is disposed in the capacity tank.

9. The protective case for an electronic device according to claim 8, the second key element further includes a stick body, and the stick body is disposed between the second key portion and the clamping portion so as to connect the second key portion and the clamping portion.

10. A protective case for an electronic device, comprising:
a case unit, and one side of the case unit including a first side portion, a second side portion and a groove portion, and a capacity space formed between the first side portion and the second side portion, and the other side of the case unit including a second capacity space and a capacity tank, wherein the groove portion includes a first groove body and a second groove body, and the first groove body is disposed on the first side portion, and the second groove body is disposed on the second side portion, wherein the second capacity space and the capacity tank are correspondingly disposed; and
a key unit including a first key element and a second key element, wherein the first key element includes an abutment portion, and the abutment portion including a first abutting end and a second abutting end, and the first abutting end and the second abutting end are correspondingly disposed, wherein the second key element includes a second key portion and a clamping portion;
wherein the first abutting end abuts against the first groove body, and the second abutting end abuts against the second groove body;
wherein the second key portion is disposed in the second capacity space, and the clamping portion is disposed in the capacity tank.
